(19) United States
(12) Patent Application Publication
(10) Pub. No.: US 2014/0140135 A1
(43) Pub. Date: May 22, 2014

(54) STORAGE DEVICE, RECOVERY METHOD, AND RECORDING MEDIUM FOR RECOVERY PROGRAM

(71) Applicant: FUJITSU LIMITED, Kawasaki-shi (JP)

(72) Inventors: Reina Okano, Hadano (JP); Hidefumi Kobayashi, Yokohama (JP); Tatsuya Yanagisawa, Kawasaki (JP); Wataru Iizuka, Kawasaki (JP)

(73) Assignee: FUJITSU LIMITED, Kawasaki-shi (JP)

(21) Appl. No.: 14/047,539

(22) Filed: Oct. 7, 2013

(30) Foreign Application Priority Data
Nov. 22, 2012 (JP) 2012-256832

(51) Int. Cl. G11C 14/00

(52) U.S. Cl. CPC G11C 14/00
USPC 365/185.08

(57) ABSTRACT

A storage device includes a control device that controls an access to storage, a volatile memory that stores data that is used for operation control of the control device, and a non-volatile memory is a backup destination of the data. Furthermore a storage device includes a detection unit that detects a failure occurred in the control device, a determination unit that determines whether or not backup data that is stored in the non-volatile memory is valid when the detection unit detects the failure occurred in the control device, and a control unit that causes the control device to execute a first processing of restoring the backup data of the non-volatile memory in the volatile memory after restart-up without backup of the data of the volatile memory, when the determination unit determines that the backup data of the non-volatile memory is valid.

### CROSS-REFERENCE TO RELATED APPLICATION

This application is based upon and claims the benefit of priority from the prior Japanese Patent Application No. 2012-256832 filed on Nov. 22, 2012, the entire contents of which are incorporated herein by reference.

### FIELD

The embodiments discussed herein are related to a storage device, a recovery method, and a recording medium for a recovery program.

### BACKGROUND

In the related art, there is a technology that avoids loss of data of a volatile memory by restarting up firmware of a control device that controls an access to storage in a storage device and backing up the data of the volatile memory in a non-volatile memory when a failure occurs in the control device. After that, the storage device is recovered by turning the power of the control device OFF/ON and restoring the data of the volatile memory by using the backed-up data.

As the related arts, there is a technology that checks whether or not processing of reading out data from a non-volatile memory to a storage medium is terminated when the power of a relay device is turned ON, and refrains from overwriting data of the storage medium over data of the non-volatile memory when the reading-out processing is not completed when the power is turned OFF. In addition, there is a technology that causes a processor to standardize an array control algorithm for a disk array and component information on the disk array and causes the processor to execute at least separation processing and aggregation processing of the data for the disk array by using a plurality of different file control programs.

However, in the related arts, it takes a long time to recover the storage device, wherein when a failure occurs in the control device in the storage device, firmware of the control device is restarted up and the power of the control device is turned OFF/ON.

Japanese Laid-open Patent Publication No. 10-191547 and Japanese Laid-open Patent Publication No. 8-147113 are examples of the related art.

### SUMMARY

According to an aspect of the invention, a storage device includes a control device that controls an access to storage, a volatile memory that stores data that is used for operation control of the control device, and a non-volatile memory is a backup destination of the data. Furthermore a storage device includes a detection unit that detects a failure occurred in the control device, a determination unit that determines whether or not backup data that is stored in the non-volatile memory is valid when the detection unit detects the failure occurred in the control device, and a control unit that causes the control device to execute a first processing of restoring the backup data of the non-volatile memory in the volatile memory after restart-up without backup of the data of the volatile memory, when the determination unit determines that the backup data of the non-volatile memory is valid.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating an example of recovery processing of a control device in a storage device according to an embodiment;

FIG. 2 is a block diagram illustrating a hardware configuration example of a storage device;

FIG. 3 is a block diagram illustrating a functional configuration example of the storage device;

FIG. 4 is a diagram illustrating an example of an operation of a CM;

FIG. 5 is a diagram illustrating an example of a CM recovery operation when both of the CMs go down in a third period;

FIG. 6 is a diagram illustrating an example of a CM recovery operation when both of the CMs go down in a fourth period;

FIG. 7 is a diagram illustrating a first example of a CM recovery operation when one of the CMs goes down in the third period and the other CM goes down in the fourth period;

FIG. 8 is a diagram illustrating a second example of the CM recovery operation when one of the CMs goes down in the third period and the other CM goes down in the fourth period;

FIG. 9 is a method illustrating an example of a procedure of CM recovery processing by a monitoring module;

FIG. 10 is a method illustrating an example of a recovery procedure processing by the CM;

FIG. 11 is a method illustrating an example of a procedure of power-off processing by the CM;

FIG. 12 is a method illustrating an example of a procedure of power-on processing by the CM;

FIG. 13 is a method illustrating an example of a procedure of abbreviated recovery processing by the CM;

FIG. 14 is a method illustrating an example of a procedure of integration processing by the CM; and

FIG. 15 is a method illustrating an example of a procedure of data copying processing by the CM.

### DESCRIPTION OF EMBODIMENTS

A storage device, a recovery method, and a recording medium for a recovery program according to the embodiments are described below in detail with reference to the accompanying drawings.

(Content of Recovery Processing of a Control Device in a Storage Device)

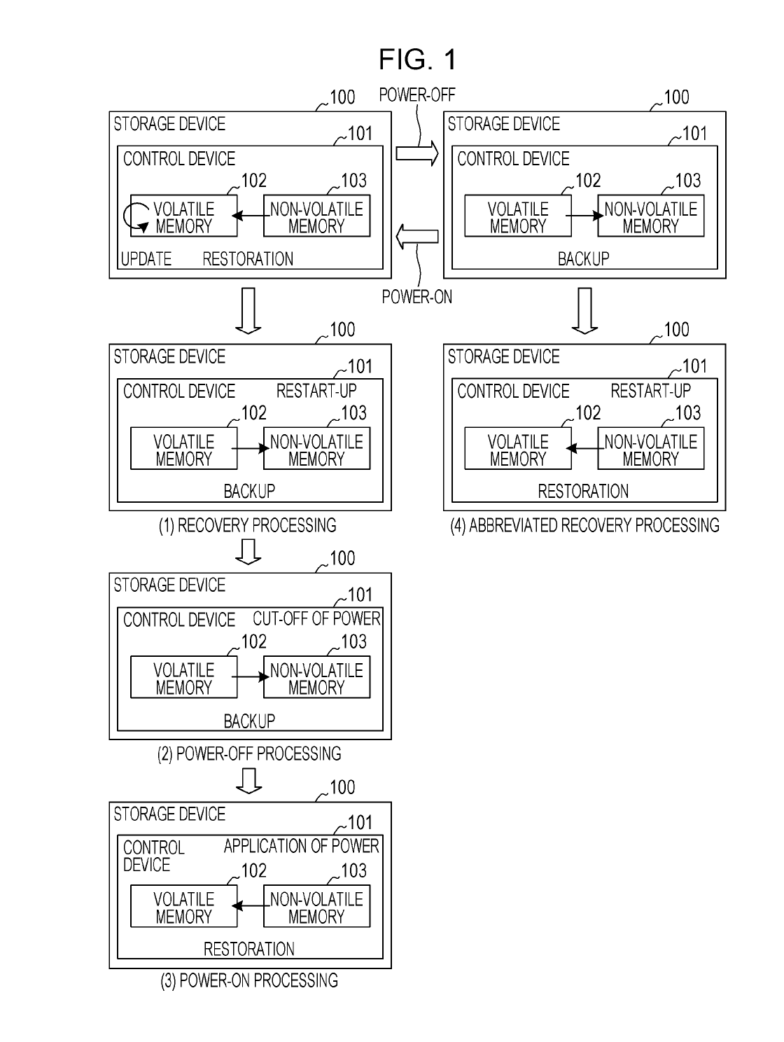

FIG. 1 is a diagram illustrating an example of recovery processing of a control device in a storage device according to an embodiment. In FIG. 1, a storage device 100 includes a control device 101. The control device 101 is a device that controls an access to storage that is included in the storage device 100, and includes a volatile memory 102 and a non-volatile memory 103.

The volatile memory 102 is a storage medium that stores data including control data. The control data is data that is used for operation control of the control device 101 and is, for example, data that indicates the state of progress of a copying session, data that indicates the configuration of the storage, or the like. The non-volatile memory 103 is a storage medium that is a backup destination of data of the volatile memory 102.

Before the power is cut off, the storage device 100 stores replicated data that is obtained by replicating the data of the volatile memory 102 in the non-volatile memory 103 as backup data to cut off the power. In addition, when the power is applied, the storage device 100 initializes the volatile memory 102 and restores the data of the volatile memory 102 by using the backup data of the non-volatile memory 103.

In addition, when the control device 101 goes down due to software malfunction or hardware malfunction, the storage device 100 recovers the control device 101 by using a different procedure depending on the state of the control device 101 at the time when the control device 101 goes down. Here, the software malfunction includes, for example, zero division, page fault, and logical inconsistency. The hardware malfunction includes, for example, temperature malfunction of the control device 101. In going down of the control device 101, it is thinkable that a central processing unit (CPU) of the control device 101 stops due to software malfunction or hardware malfunction, and the control device 101 does not accepts a response.

First, a case is described in which the control device 101 goes down during a time from restoration of the data of the volatile memory 102 by using the backup data of the non-volatile memory 103 after application of the power, to cutting-off of the power (hereinafter may be referred to as “first period”), and the recovery processing of the control device 101 is described.

<Example of Recovery Processing of the Control Device 101 when the Control Device 101 Goes Down in the First Period>

In this case, the backup data of the non-volatile memory 103 of the control device 101 is not valid. When the backup data of the non-volatile memory 103 is not valid, data to be stored in the volatile memory 102 at the time when the control device 101 is recovered is not backup data of the non-volatile memory 103 at the time when the control device 101 goes down.

That is, when the backup data of the non-volatile memory 103 is not valid, data to be stored in the volatile memory 102 at the time when the control device 101 is recovered is data of the volatile memory 102 at the time when the control device 101 goes down. Therefore, the storage device causes the control device 101 to overwrite the data of the volatile memory 102 over backup data of the non-volatile memory 103 before the power is cut off and causes the control device 101 to restore the data of the volatile memory 102 after the power is applied again.

(1) The storage device 100 causes the control device 101 to execute the recovery processing. In the recovery processing, the control device 101 restarts up software that controls the control device 101 without cutting-off of the power and stores replicated data that is obtained by replicating the data of the volatile memory 102 in the non-volatile memory 103 as backup data. The software is, for example, firmware. Therefore, the storage device 100 proceeds to a state in which the control device 101 is allowed to operate without initialization of data of the volatile memory 102 and may cause the control device 101 to back up the data of the volatile memory 102 at the time when the control device 101 goes down.

(2) The storage device 100 causes the control device 101 to execute the power-off processing. In the power-off processing, the control device 101 stores the replicated data that is obtained by replicating the data of the volatile memory 102 in the non-volatile memory 103 as backup data, and the power is cut off. Therefore, the storage device 100 may cause the control device 101 to back up the data of the volatile memory 102 at the time when the power-off processing is executed.

(3) The storage device 100 causes the control device 101 to execute the power-on processing. In the power-on processing, in the control device 101, the power is applied, and the control device 101 initializes the volatile memory 102 and restores the data of the volatile memory 102 by using the backup data of the non-volatile memory 103. Therefore, the storage device 100 may recover the control device 101 back to the state before the control device 101 goes down.

A case is described in which the control device 101 goes down during a time from initialization of the volatile memory 102 after the power is applied, to restoration of the data of the volatile memory 102 by using the backup data of the non-volatile memory 103 (hereinafter may be referred to as “second period”), and the recovery processing of the control device 101 is described below.

<Example of Recovery Processing of the Control Device 101 when the Control Device 101 Goes Down in the Second Period>

In this case, the backup data of the non-volatile memory 103 of the control device 101 is valid. In the case that the backup data of the non-volatile memory 103 is valid, data to be stored in the volatile memory 102 at the time when the control device 101 is recovered is backup data of the non-volatile memory 103 at the time when the control device 101 goes down.

That is, when the backup data of the non-volatile memory 103 is valid, it is indicated that the data of the volatile memory 102 at the time when the control device 101 goes down is data that may be lost. Therefore, the control device 101 initializes the volatile memory 102 and restores the data of the volatile memory 102 by using the backup data of the non-volatile memory 103.

(4) The storage device 100 causes the control device 101 to execute the abbreviated recovery processing. In the abbreviated recovery processing, the control device 101 restarts up software that controls the control device 101 without cutting-off of the power, initializes the volatile memory 102, and restores the data of the volatile memory 102 by using the backup data of the non-volatile memory 103. Therefore, the storage device 100 may recover the control device 101 back to the state before the control device 101 goes down.

As described above, the storage device 100 changes a recovery procedure depending on whether the control device 101 goes down in the first period or the second period. Therefore, when the control device 101 goes down in the first period, the storage device 100 causes the control device 101 to back up the data of the volatile memory 102 and may recover the control device 101 back to the state before the control device 101 goes down.

In addition, when the control device 101 goes down in the second period, the storage device 100 does not cause the control device 101 to back up the data of the volatile memory 102, so that overwriting of initialized data over the backup data of the non-volatile memory 103 may be avoided. As a result, the storage device 100 may recover the control device 101 back to the state before the control device 101 goes down. In addition, the storage device 100 does not cause the control device 101 to execute the processing of backing up the data of the volatile memory 102, so that recovery of the control device 101 may be speeded up.

In the example of FIG. 1, the recovery procedure is changed depending on whether the control device 101 goes down in the first period or the second period, and the embodiment is not limited to such a case. For example, the recovery procedure may be changed depending on whether the control device 101 goes down during a period from update of the data of the volatile memory 102 to cutting-off of the power or a period from initialization of the volatile memory 102 to update of the data of the volatile memory 102.

(Hardware Configuration Example of the Storage Device 100)

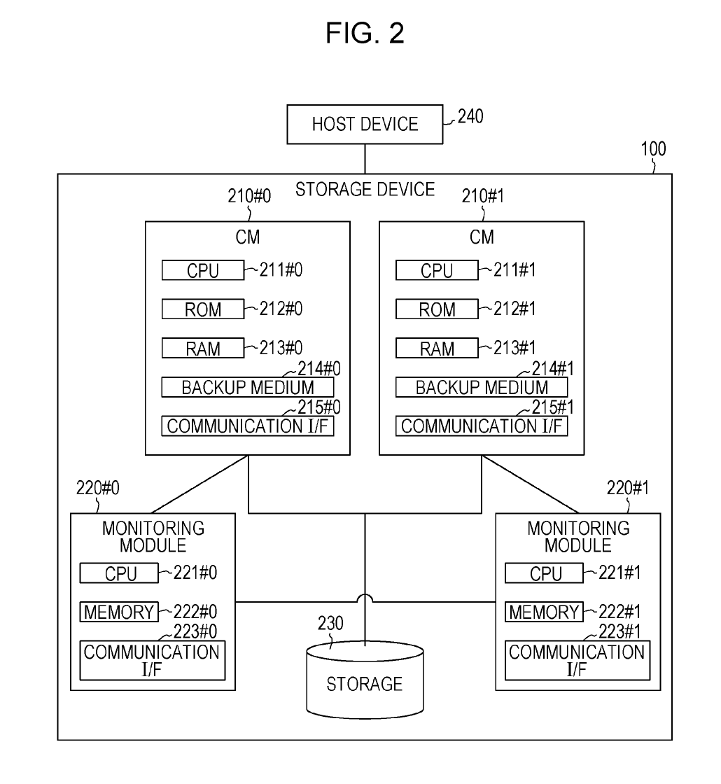

A hardware configuration example of the storage device 100 according to the embodiment is described below. FIG. 2 is a block diagram illustrating a hardware configuration example of the storage device 100. In FIG. 2, the storage device 100 includes control modules (CMs) 210#0 and 210#1, monitoring modules 220#0 and 220#1, and storage 230. In addition, the storage device 100 is connected to a host device 240. In the description below, a certain CM may be referred to as “CM 210”. In addition, a certain monitoring module may be referred to as “monitoring module 220”.

The storage device 100 is a computer that stores data that is input from the host device 240 in the storage 230 and outputs data of the storage 230 to the host device 240.

The CM 210#0 is an example of the control device 101 illustrated in FIG. 1 and is a device that controls an access to the storage 230. In addition, the CM 210 starts up a CM 210 that is not started up yet when there is the CM 210 that is not started up yet.

The CM 210#0 includes a CPU 211#0, a read only memory (ROM) 212#0, a random access memory (RAM) 213#0, a backup medium 214#0, and a communication interface (I/F) 215#0. In addition, the configuration elements of the CM 210#0 are connected to each other, for example, through a bus (not illustrated).

The CPU 211#0 controls the whole CM 210#0. In the description below, a CPU that is included in a certain CM 210 may be referred to as “CPU 211”. The ROM 212#0 stores a program such as a boot program. In the description below, a ROM that is included in a certain CM 210 may be referred to as “ROM 212”.

The RAM 213#0 is an example of the volatile memory 102 illustrated in FIG. 1, and stores data that includes control data that is used for operation control of the CM 210#0. The control data includes, for example, data that indicates the state of progress of the copying session and data that indicates the configuration of the storage 230. In addition, the RAM 213#0 stores a flag that indicates whether or not backup data of the backup medium 214#0 is valid. In addition, the RAM 213#0 is used as a work area of the CPU 211#0. In the description below, a RAM that is included in a certain CM 210 may be referred to as “RAM 213”.

The backup medium 214#0 is an example of the non-volatile memory 103 illustrated in FIG. 1 and is used as a backup destination of data in the RAM 213#0. In the description below, a backup medium that is included in a certain CM 210 may be referred to as “backup medium 214”.

The communication I/F 215#0 controls communication between the monitoring modules 220#0 and 220#1, the storage 230, and the host device 240. In the description below, a communication I/F that is included in a certain CM 210 may be referred to as “communication I/F 215”. The description of the CM 210#1 is the same as that of the CM 210#0 and is omitted herein.

The monitoring module 220#0 is a device that is connected to the CM 210#0 and that detects that the CM 210#0 goes down. In addition, the monitoring module 220#0 is connected to the monitoring module 220#1 and receives a notification that indicates that the CM 210#1 goes down, from the monitoring module 220#1. When all of the CMs 210 goes down, the monitoring module 220#0 executes the recovery processing illustrated in FIG. 1, causes the CM 210#0 to execute the recovery processing, the power-off processing, the power-on processing, or the abbreviated recovery processing to recover the CM 210#0.

The monitoring module 220#0 includes a CPU 221#0, a memory 222#0, and a communication I/F 223#0. In addition, the configuration elements of the monitoring module 220#0 are connected to each other, for example, through a bus (not illustrated). Here, the CPU 221#0 controls the whole monitoring module 220#0. In the description below, a CPU that is included in a certain monitoring module 220 may be referred to as “CPU 221”.

The memory 222#0 stores a program such as a boot program and a recovery program. In the description below, a memory that is included in a certain monitoring module 220 may be referred to as “memory 222”. The communication I/F 223#0 controls communication with the CM 210#0. In the description below, a communication I/F that is included in a certain monitoring module 220 may be referred to as “communication I/F 223”. The description of the monitoring module 220#1 is the same as that of the monitoring module 220#0 and is omitted herein.

The storage 230 is a magnetic disk and stores data that is written by the control of the CM 210. A plurality of magnetic disks may be employed as the storage 230, and a technology of redundant arrays of inexpensive disks (RAID) may be applied to the storage 230. The host device 240 is a computer that transmits a request to store data into the storage 230 and a request to read out data of the storage 230, to the storage device 100.

In the description of FIG. 2, the case is described above in which there are two CMs, and the embodiment is not limited to such a case. For example, there may be a single CM 210 or three or more CMs 210. In addition, in the description of FIG. 2, the case is described above in which there are the two monitoring modules 220, and the embodiment is not limited to such a case. For example, there may be a single monitoring module 220 or three or more monitoring modules 220. In addition, in the description of FIG. 2, the case is described above in which the storage 230 is the magnetic disk, and the embodiment is not limited to such a case. For example, the storage 230 may be an optical disk or a magnetic tape.

(Functional Configuration Example of the Storage Device 100)

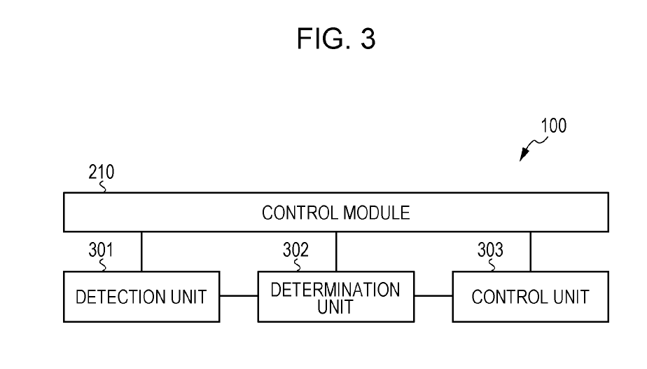

The functional configuration example of the storage device 100 is described below with reference to FIG. 3. FIG. 3 is a block diagram illustrating the functional configuration example of the storage device 100. The storage device 100 includes a detection unit 301, a determination unit 302, and a control unit 303. The functions of the detection unit 301, the determination unit 302, and the control unit 303 are implemented, for example, by causing the CPU 221 to execute a program that is stored in the storage device such as the memory 222 of the monitoring module 220 illustrated in FIG. 2 or by the communication I/F 223.

In addition, as described above, the storage device 100 includes the control device 101. The control device 101 is a device that controls an access to the storage 230 and is, for example, the CM 210 illustrated in FIG. 2. There may be a plurality of CMs 210. The CM 210 includes the volatile memory 102 and the non-volatile memory 103.

The volatile memory 102 is a storage medium that stores data that includes control data that is used for operation control of the CM 210 and is, for example, the RAM 213 illustrated in FIG. 2. In addition, the volatile memory may be a storage medium that exists outside the CM 210 and that the CM 210 may access. The non-volatile memory 103 is a storage medium that is a backup destination of data of the volatile memory 102 and is, for example, the backup medium 214 illustrated in FIG. 2. The non-volatile memory may be a memory that exists outside the CM 210 and that the CM 210 may access.

When there is a failure in the CM 210 and the CM 210 goes down, the CM 210 transmits a notification that indicates that the CM 210 goes down, to the detection unit 301 just before going down. In addition, when a failure occurs in the CM 210 and the CM 210 goes down, the CM 210 may store information that indicates that the CM 210 goes down, in the ROM 212 just before going down.

The CM 210 includes a flag that indicates whether or not backup data of the backup medium 214 is valid. For example, when the CM 210 initializes the RAM 213 or backs up the data of the RAM 213 into the backup medium 214, the CM 210 sets the flag valid. In addition, the CM 210 sets the flag invalid, for example, when the backup data of the backup medium 214 is recovered to the RAM 213 or when the data of the RAM 213 is updated.

In addition, when a CM 210 that is not started up yet is detected, a CM 210 that has been already started up restarts up the CM 210 that is not started up yet and transmits data of the RAM 213 that is included in the CM 210 that has been already started up, to the CM 210 that has been started up now. In addition, when the CM 210 that is not started up yet is restarted up by the other CM 210, the CM 210 receives data from the other CM 210 and stores the received data in the RAM 213 that is included in the CM 210.

The detection unit 301 detects that a failure occurs in the CM 210. The detection unit 301 detects that the CM 210 goes down, for example, by receiving a notification of information that indicates a CM 210 that is connected to the detection unit 301 goes down, from the CM 210. In addition, the detection unit 301 may detect that the CM 210 goes down by checking whether or not there is information that indicates that the CM 210 has gone down, in the ROM 212 that is included in the CM 210, at certain time intervals.

When there is a plurality of CMs 210, the detection unit 301 detects that each of the plurality of CMs 210 goes down. For example, the detection unit 301 receives the notification of the information that indicates the CM 210 that is connected to the detection unit 301 goes down, from the CM 210, and receives the notification of the information that indicates a CM 210 to which another monitoring module 220 is connected goes down, from the monitoring module 220. Therefore, the detection unit 301 detects that the plurality of CMs 210 go down. The detection result is stored, for example, in the memory 222 in the monitoring module 220. Therefore, the detection unit 301 may generate a trigger that causes the CM 210 to be recovered.

When the detection unit 301 detects that a failure occurs in the CM 210, the determination unit 302 determines whether or not backup data that is stored in the backup medium 214 is valid. In addition, when there is the plurality of CMs 210, the detection unit 301 may detect the occurrences of failures in the plurality of CMs 210. In such a case, the determination unit 302 determines whether or not backup data of the backup medium 214 that is included in each of the plurality of CMs 210 is valid.

For example, when the detection unit 301 detects that the CM 210 goes down, the determination unit 302 refers to a flag of the ROM 212 that is included in the CM 210 that has gone down. In addition, when the flag is valid, the determination unit 302 determines that the backup data of the backup medium 214 is valid. In addition, for example, the determination unit 302 receives a notification of information that indicates whether or not the flag of the ROM 212 that is included in the CM 210 to which another monitoring module 220 is connected is valid, from the monitoring module 220. Therefore, the determination unit 302 determines whether or not backup data in the plurality of CMs 210 is valid. The determination result is stored, for example, in the memory 222 in the monitoring module 220. Therefore, the control unit 303 may select the recovery procedure of the CM 210 depending on the determination result by the determination unit 302.

When the determination unit 302 determines that the backup data of the backup medium 214 is valid, the control unit 303 causes the CM 210 to execute first processing. Here, the first processing is, for example, processing of restoring the backup data of the backup medium 214 to the RAM 213 after the data of the RAM 213 is restarted up without backup. The first processing is, for example, the abbreviated recovery processing illustrated in FIG. 1.

In addition, when the determination unit 302 determines that the backup data of the backup medium 214 is not valid, the control unit 303 causes the CM 210 to execute second processing and third processing sequentially. Here, the second processing is, for example, processing of backing up the data of the RAM 213 into the backup medium 214 after the RAM 213 is restarted up without initialization. The second processing is, for example, the recovery processing illustrated in FIG. 1.

The third processing is, for example, processing of restoring the backup data of the backup medium 214 to the RAM 213 after the data of the RAM 213 is backed up into the backup medium 214 and the RAM 213 is restarted up. The third processing is, for example, the power-off processing and the power-on processing illustrated in FIG. 1.

In addition, in the case in which there is the plurality of the CMs 210, when the determination unit 302 determines that each of the CMs 210 is valid, the control unit 303 causes each of the CMs 210 to execute the first processing. In addition, in the case in which there is the plurality of the CMs 210, when the determination unit 302 determines that each of the CMs 210 is not valid, the control unit 303 causes each of the CMs 210 to execute to the second processing and the third processing sequentially.

In addition, a case is described in which a first CM 210 in which it is determined that the backup data of the backup medium 214 is valid and a second CM 210 in which it is determined that the backup data of the backup medium 214 is not valid exist in the plurality of CMs 210. Here, the following description is made by regarding the first CM 210 as the CM 210#0 and regarding the second CM 210 as the CM 210#1. In such a case, the control unit 303 causes the CM 210#0 to execute the second processing and the third processing sequentially.

Here, the CM 210#0 detects the CM 210#1 that is not started up yet after executing the third processing. In addition, the CM 210#0 may detect the CM 210#1 that is not started up yet by receiving information that indicates the CM 210#1 that is not started up yet, from the monitoring module 220. When the CM 210#0 detects the CM 210#1 that is not started up yet, the CM 210#0 causes the CM 210#1 to restart the software and transmits data of the RAM 213#0 that is included in the CM 210#0 to the CM 210#1.

In addition, the CM 210#1 stores the data that is received from the CM 210#0 in the RAM 213#1 that is included in the CM 210#1 after being restarted up by the CM 210#0. Therefore, the control unit 303 may recover the CM 210 and the storage device.

(Examples of a CM Recovery Operation in the Storage Device 100)

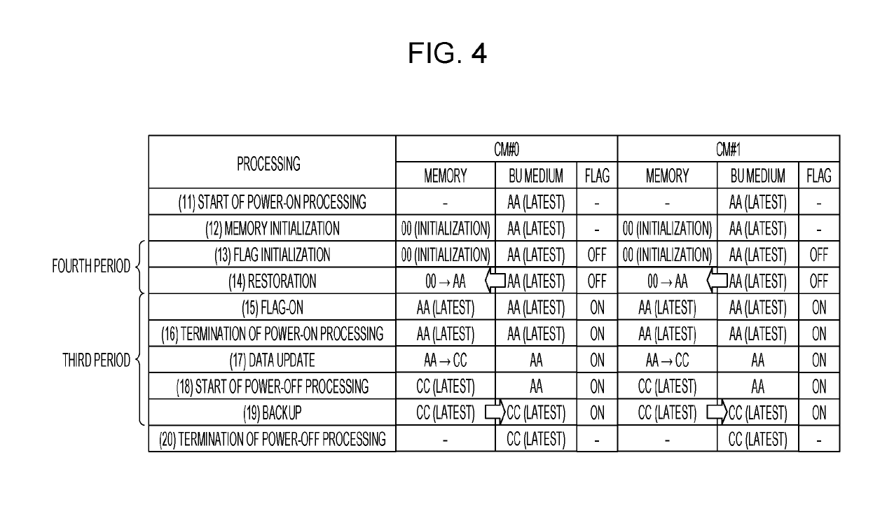

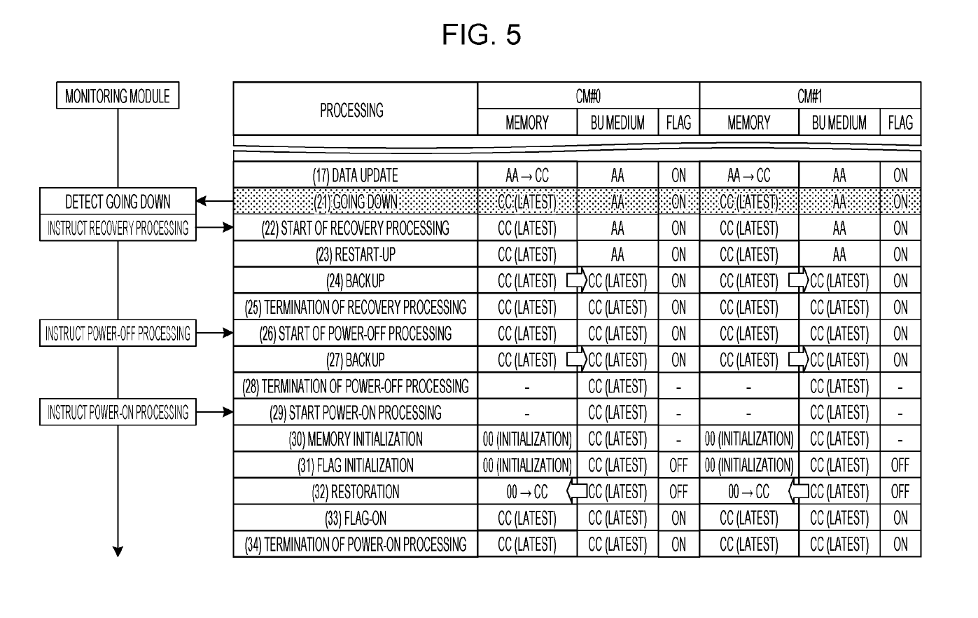

Examples of a CM recovery operation in the storage device 100 are described below with reference to FIGS. 4 to 8. In the description below, an example of the operation of the CM 210 is illustrated in FIG. 4, and examples of a CM recovery operation that is executed depending on a period during which the CM 210 goes down when the CM 210 goes down during the operation illustrated in FIG. 4 are illustrated in FIGS. 5 to 8.

<Example of an Operation of the CM 210>

First, the example of the operation of the CM 210 is described with reference to FIG. 4. FIG. 4 is a diagram illustrating the example of the operation of the CM 210. In FIG. 4, (11) in each of the CMs 210, the power is applied, and power-on processing is started. Here, data is not stored in the RAM 213 because the power is being cut off. In the backup medium 214, backup data “AA” is stored. A flag is not set to the CM 210.

(12) Each of the CMs 210 initializes the RAM 213. Here, initialized data “00” is stored in in the RAM 213. (13) Each of the CMs 210 is in a state in which backup data of the backup medium 214 is to be overwritten in the RAM 213, so that it is determined that the backup data is valid, and the flag is initialized. Here, “OFF” is flagged due to the initialization. Here, “OFF” indicates that the backup data is valid.

(14) Each of the CM 210 restores data of the RAM 213 by using the backup data “AA” of the backup medium 214. Here, in the RAM 213, the data “AA” is stored. (15) Each of the CMs 210 is in a state in which the backup data of the backup medium 214 is not to be overwritten over the data of the RAM 213, so that it is determined that the backup data is not valid, and “ON” is flagged. Here, “ON” is flagged. Here, “ON” indicates that the backup data is not valid. (16) Each of the CMs 210 terminates the power-on processing. Therefore, in each of the CMs 210, the flow proceeds to a regular operation to control an access to the storage 230.

(17) Each of the CMs 210 updates the data of the RAM 213 during the regular operation. Here, it is assumed that data “CC” is stored in the RAM 213. (18) Each of the CMs 210 starts the power-off processing. (19) Each of the CMs 210 stores replicated data that is obtained by replicating the data of the RAM 213 in the backup medium 214 as backup data. Here, the backup data “CC” is stored in the backup medium 214.

(20) In each of the CMs 210, the power is cut off and each of the CMs 210 terminates the power-off processing. Here, the data “CC” of the RAM 213 is deleted because the RAM 213 is volatile and the power is cut off. Similarly, the setting of the flag is also deleted.

When the CM 210 goes down during the operation illustrated in FIG. 4, the storage device 100 changes the recovery procedure of the CM 210 depending on whether or not backup data of the backup medium 214 at the time when the CM 210 goes down is valid. For example, the CM 210 is recovered by the monitoring module 220 in the storage device 100.

The third period illustrated in FIG. 4 is a period in which backup data is determined to be not valid due to the data of the RAM 213 and a period in which the flag is set to “ON”. In addition, the fourth period illustrated in FIG. 4 is a period in which backup data is determined to be valid due to the data of the RAM 213 and a period in which the flag is set to “OFF”.

The starting point of the third period and the ending point of the fourth period may be points at which the data update of (17) has been completed. The ending point of the third period and the starting point of the fourth period may be points at which the backup of (19) has been completed. In this case, for example, the flag is realized by a non-volatile storage area such as the ROM 212 in order to keep the flag even after the power is cut off.

<Example of a CM Recovery Operation when Both of the CMs 210 Go Down in the Third Period>

An operation of CM recovery when both of the CMs 210 go down in the third period illustrated in FIG. 4 is described below with reference to FIG. 5.

FIG. 5 is a diagram illustrating an example of the CM recovery operation when both of the CMs 210 go down in the third period. In FIG. 5, a case is described in which (21) each of the CMs 210 goes down after the data update of (17) illustrated in FIG. 4 is terminated. In this case, the monitoring module 220 detects that each of the CMs 210 goes down and checks the flag of each of the CMs. The monitoring module 220 transmits a start instruction of the recovery processing to each of the CMs 210 because the flag of each of the CMs is set to “ON”.

(22) Each of the CMs 210 receives the start instruction of the recovery processing and starts the recovery processing. (23) Each of the CMs 210 restarts the software. Here, in each of the CMs 210, the power is not cut off, so that the data “CC” of the RAM 213 is not deleted.

(24) Each of the CMs 210 stores replicated data that is obtained by replicating the data of the RAM 213 in the backup medium 214 as backup data. Here, the backup data “CC” is stored in the backup medium 214. (25) Each of the CMs 210 terminates the recovery processing and transmits a termination notification to the monitoring module 220.

The monitoring module 220 detects that each of the CMs 210 terminates the recovery processing, and transmits a start instruction of the power-off processing, to each of the CMs 210. (26) Each of the CMs 210 starts the power-off processing. (27) Each of the CMs 210 stores the replicated data that is obtained by replicating the data of the RAM 213 in the backup medium 214 as backup data. Here, the backup data “CC” is stored in the backup medium 214. (28) In each of the CMs 210, the power is cut off, and each of the CMs 210 terminates the power-off processing and transmits a termination notification to the monitoring module 220. Here, the data “CC” of the RAM 213 is deleted because the power is cut off. Similarly, the setting of the flag is also deleted.

The monitoring module 220 detects that each of the CMs 210 terminates the power-off processing, and transmits a start instruction of the power-on processing, to each of the CMs 210. (29) When each of the CMs 210 receives the start instruction of the power-on processing, the power is applied, and the power-on processing is started. Here, data is not stored in the RAM 213 because the power is cut off. The backup data “CC” is stored in the backup medium 214. The flag is not set to the CM 210.

(30) Each of the CMs 210 initializes the RAM 213. Here, the initialized data “00” is stored in the RAM 213. (31) Each of the CMs 210 determines that the backup data is valid and initializes the flag. Here, “OFF” is flagged due to the initialization. (32) Each of the CMs 210 restores the data of the RAM 213 by using the backup data “CC” of the backup medium 214. Here, the data “CC” is stored in the RAM 213.

(33) Each of the CMs 210 determines that the backup data is not valid and sets the flag to “ON”. Here, “ON” is flagged. (34) Each of the CMs 210 terminates the power-on processing. Therefore, the monitoring module 220 causes each of the CMs 210 to back up the data of the volatile memory 102 and may recover each of the CMs 210 back to the state before each of the CMs 210 goes down.

<Example of a CM Recovery Operation when Both of the CMs 210 Go Down in the Fourth Period>

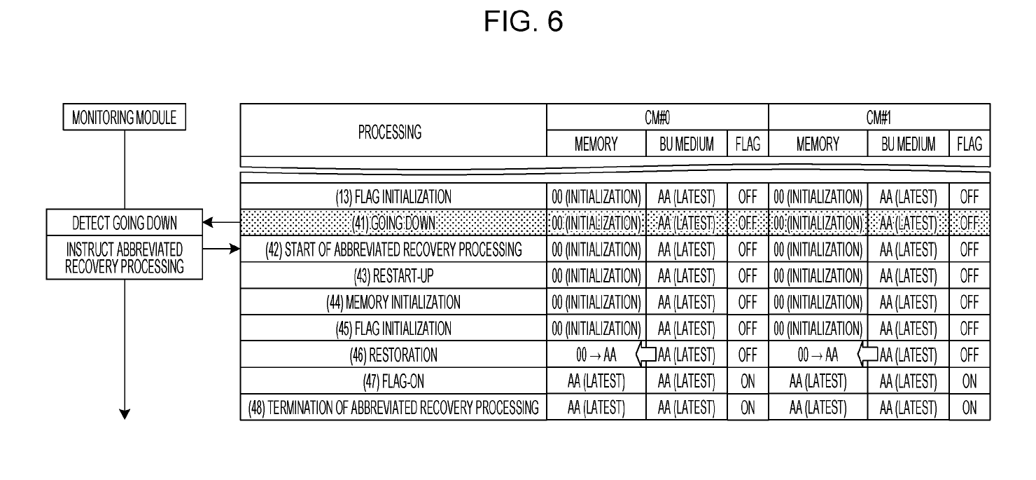

A CM recovery operation when both of the CMs 210 go down in the fourth period illustrated in FIG. 4 is described below with reference to FIG. 6.

FIG. 6 is a diagram illustrating an example of the CM recovery operation when both of the CMs 210 go down in the fourth period. In FIG. 6, a case is described in which (41) each of the CMs 210 goes down after the flag initialization of (13) illustrated in FIG. 4 is terminated. In this case, the monitoring module 220 detects that each of the CMs 210 goes down and checks the flag of each of the CMs. The monitoring module 220 transmits a start instruction of the abbreviated recovery processing, to each of the CMs 210 because the flag of each of the CMs is set to “OFF”.

(42) When each of the CMs 210 receives the start instruction of the abbreviated recovery processing, each of the CMs 210 starts the abbreviated recovery processing. (43) Each of the CMs 210 restarts up the software (for example, firmware). Here, the data “00” is stored in the RAM 213. The backup data “AA” is stored in the backup medium 214. “OFF” is flagged.

(44) Each of the CMs 210 initializes the RAM 213. Here, the initialized data “00” is stored in the RAM 213. (45) Each of the CMs 210 initializes the flag. Here, “OFF” is flagged due to the initialization.

(46) Each of the CMs 210 restores the data of the RAM 213 by using the backup data “AA” of the backup medium 214. Here, the data “AA” is stored in the RAM 213. (47) Each of the CMs 210 sets the flag to “ON”. Here, “ON” is flagged. (48) Each of the CMs 210 terminates the abbreviated recovery processing.

Therefore, the monitoring module 220 may avoid overwriting of the initialized data over the backup data of the non-volatile memory 103 because the monitoring module 220 does not cause each of the CMs 210 to back up the data of the volatile memory 102. As a result, the monitoring module 220 may recover each of the CMs 210 back to the state before each of the CMs 210 goes down. In addition, the monitoring module 220 may speed up the recovery of the CM 210 because the monitoring module 220 does not cause each of the CMs 210 to back up the data of the volatile memory 102.

<Example of a CM Recovery Operation when One of the CMs 210 Goes Down in the Third Period and the Other CM 210 Goes Down in the Fourth Period>

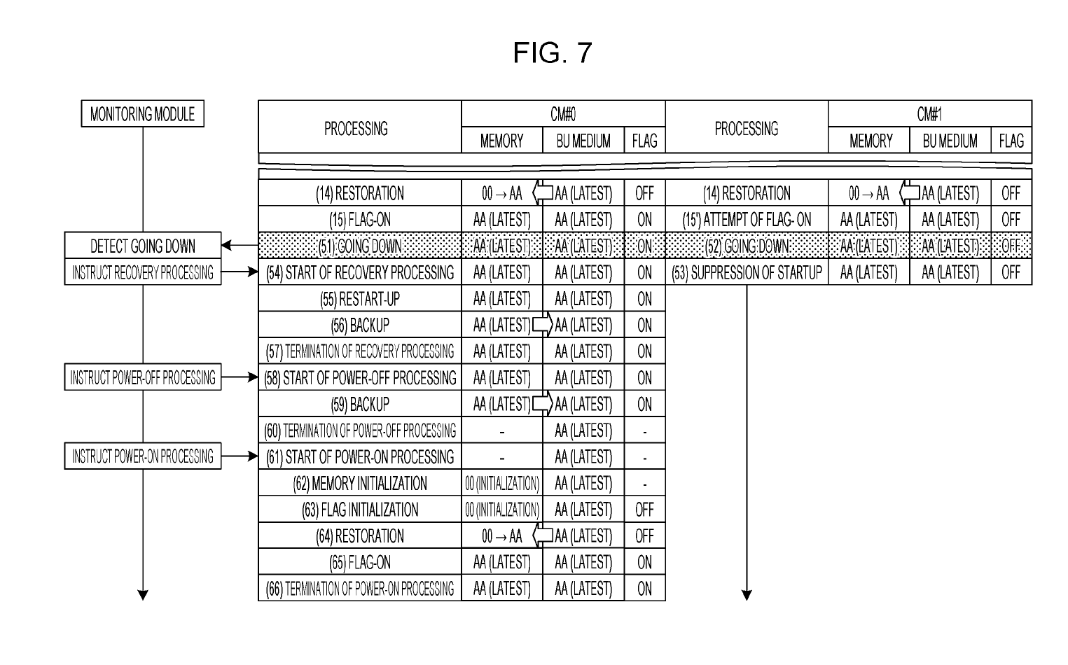

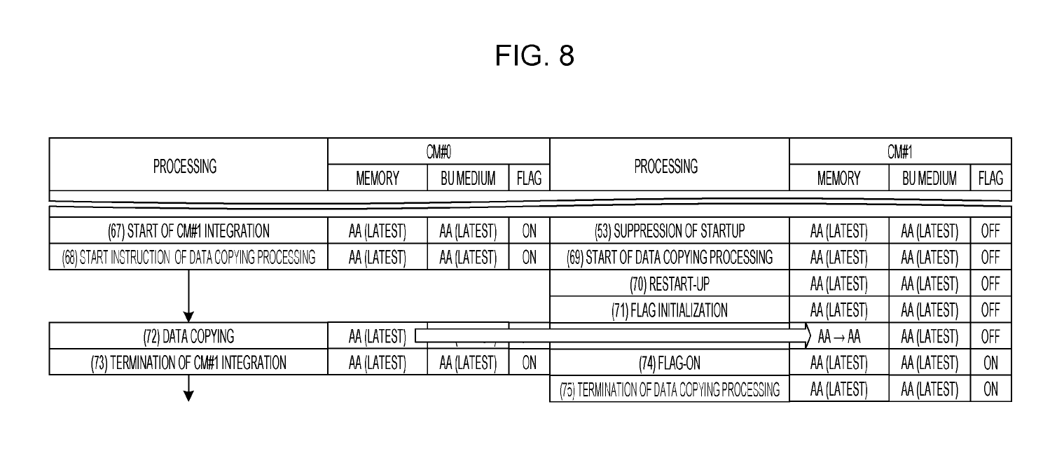

A CM recovery operation when one of the CMs 210 goes down in the third period illustrated in FIG. 4 and the other CM 210 goes down in the fourth period illustrated in FIG. 4 is described below with reference to FIGS. 7 and 8.

FIGS. 7 and 8 are diagrams illustrating an example of the CM recovery operation when the one of the CMs 210 goes down in the third period and the other CM 210 goes down in the fourth period. In FIG. 7, a case is described in which (51) the CM 210#0 goes down when the flag-“ON” setting of (15) illustrated in FIG. 4 is terminated, and (52) the CM 210#1 goes down before the restoration of (14) illustrated in FIG. 4 is terminated and the flag-“ON” setting of (15) is terminated.

In this case, the monitoring module 220 detects that each of the CMs 210 goes down and checks the flag of each of the CMs. The monitoring module 220 suppresses the start-up of the CM 210#1 the flag of which is set to “OFF” and transmits a start instruction of the recovery processing to the CM 210#0 the flag of which is set to “ON” because the “ON” state and the “OFF” state are mixed in the flags of the CMs.

(53) The start-up of the CM 210#1 is suppressed. (54) The CM 210#0 receives the start instruction of the recovery processing and starts the recovery processing. (55) The CM 210#0 restarts up the software. Here, the data “AA” of the RAM 213 is not deleted because the power is not cut off in the CM 210#0.

(56) The CM 210#0 stores the replicated data that is obtained by replicating the data of the RAM 213 in the backup medium 214 as backup data. Here, the backup data “AA” is stored in the backup medium 214. (57) The CM 210#0 terminates the recovery processing and transmits a termination notification to the monitoring module 220.

The monitoring module 220 detects that the CM 210#0 terminates the recovery processing and transmits a start instruction of the power-off processing to the CM 210#0. (58) The CM 210#0 starts the power-off processing. (59) The CM 210#0 stores the replicated data that is obtained by replicating the data of the RAM 213 in the backup medium 214 as backup data. Here, the backup data “AA” is stored in the backup medium 214. (60) In the CM 210#0, the power is cut off, and the CM 210#0 terminates the power-off processing and transmits a termination notification to the monitoring module 220. Here, the data “AA” of the RAM 213 is deleted because the power is cut off. Similarly, the setting of the flag is also deleted.

The monitoring module 220 detects that the CM 210#0 terminates the power-off processing and transmits a start instruction of the power-on processing to the CM 210#0. (61) In the CM 210#0, the power is applied, and the CM 210#0 starts the power-on processing. Here, data is not stored in the RAM 213 because the power is cut off. The backup data “AA” is stored in the backup medium 214. The flag is not set to the CM 210.

(62) The CM 210#0 initializes the RAM 213. Here, the initialized data “00” is stored in the RAM 213. (63) The CM 210#0 determines that the backup data is valid and initializes the flag. Here, “OFF” is flagged due to the initialization.

(64) The CM 210#0 restores the data of the RAM 213 by using the backup data “AA” of the backup medium 214. Here, the data “AA” is stored in the RAM 213. (65) The CM 210#0 determines that the backup data is not valid and sets the flag to “ON”. Here, “ON” is flagged. (66) The CM 210#0 terminates the power-on processing.

Therefore, the monitoring module 220 causes the CM 210#0 to back up the data of the volatile memory 102, and the CM 210#0 may be recovered back to the state before the CM 210#0 goes down. After that, in each of the CMs 210, the flow proceeds to the operation illustrated in FIG. 8.

In FIG. 8, (67) the CM 210#0 starts the integration processing when the CM 210#0 detects the CM 210#1 that is not started up yet. (68) The CM 210#0 transmits a start instruction of the data copying processing. (69) When the CM 210#1 receives the start instruction of the data copying processing, the CM 210#1 starts the data copying processing. (70) The CM 210#1 restarts up the software. (71) The CM 210#1 initializes the flag. Here, “OFF” is flagged.

(72) The CM 210#0 transmits the data of the RAM 213 to the CM 210#1. In addition, the CM 210#1 receives data from the CM 210#0 and stores the received data in the RAM 213. (73) The CM 210#0 terminates the integration processing.

(74) The CM 210#1 sets the flag to “ON”. Here, “ON” is flagged. (75) The CM 210#1 terminates the data copying processing. Therefore, the monitoring module 220 may recover the CM 210 having the newer data of the RAM 213, from among the CMs 210. As a result, the CM 210 having the older data of the RAM 213 is recovered by the CM 210 having the newer data of the RAM 213, and the pieces of control data of the CMs 210 become identical.

(Procedure of the CM Recovery Processing)

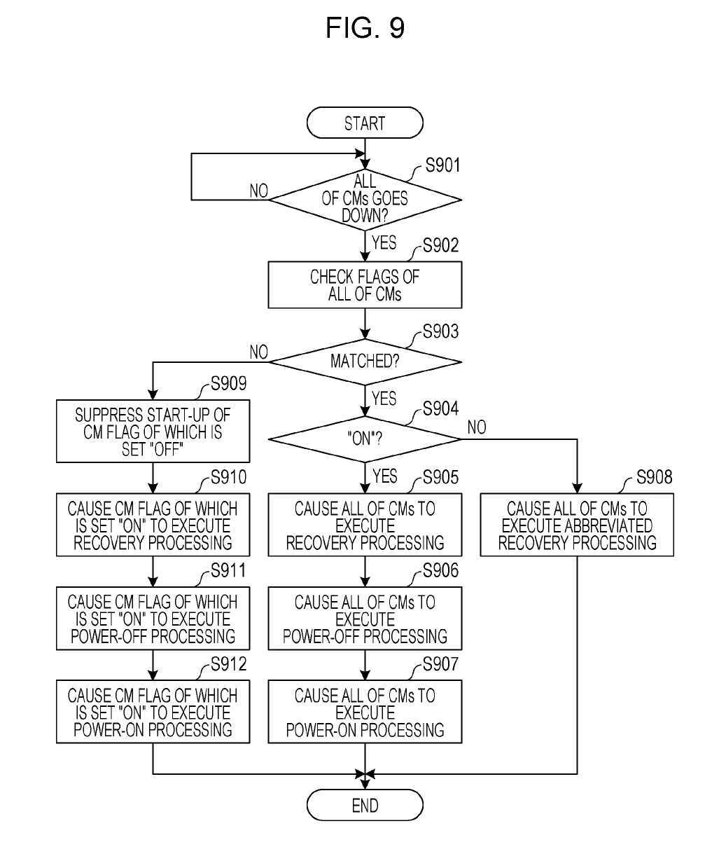

An example of a procedure of the CM recovery processing by the monitoring module 220 is described below with reference to FIG. 9.

FIG. 9 is a method illustrating the example of the procedure of the CM recovery processing by the monitoring module 220. In FIG. 9, the monitoring module 220 determines whether or not all of the CMs 210 goes down (Step S901).

Here, when there is a CM 210 that does not go down (Step S901: No), in the monitoring module 220, the flow returns to the processing of Step S901. In addition, all of the CMs 210 go down (Step S901: Yes), the monitoring module 220 checks flags of all of the CMs 210 (Step S902).

After that, the monitoring module 220 determines whether or not the statuses of checked flags of all of the CMs 210 are matched with each other (Step S903). Here, when the statuses of the flags of all of the CMs 210 are matched with each other (Step S903: Yes), the monitoring module 220 determines whether or not the statuses of the flags are matched with each other as “ON” (Step S904).

Here, when the statuses of the flags are matched with each other as “ON” (Step S904: Yes), the monitoring module 220 transmits a start instruction of the recovery processing to all of the CMs 210 and causes all of the CMs 210 to execute the recovery processing (Step S905).

After that, the monitoring module 220 transmits a start instruction of the power-off processing to all of the CMs 210, causes all of the CMs 210 to execute the power-off processing (Step S906), transmits a start instruction of the power-on processing to all of the CMs 210, and causes all of the CMs 210 to execute the power-on processing (Step S907). In addition, the monitoring module 220 terminates the CM recovery processing.

The operation of CM recovery illustrated in FIG. 5 is implemented by the processing through Steps S901 to S907. Therefore, the monitoring module 220 causes each of the CMs 210 to back up the data of the volatile memory 102 so as to recover each of the CMs 210 back to the state before each of the CMs 210 goes down.

In addition, in Step S904, when the statuses of the flags are matched with each other as “OFF” (Step S904: No), the monitoring module 220 transmits a start instruction of the abbreviated recovery processing, to all of the CMs 210, and causes all of the CMs 210 to execute the abbreviated recovery processing (Step S908). In addition, the monitoring module 220 terminates the CM recovery processing.

The operation of CM recovery illustrated in FIG. 6 is implemented by the processing through Steps S901 to S904, and Step S908. Therefore, the monitoring module 220 may avoid the overwriting of the initialized data over the backup data of the non-volatile memory 103 because the monitoring module 220 does not cause each of the CMs 210 to back up the data of the volatile memory 102. As a result, the monitoring module 220 may recover each of the CMs 210 back to the state before each of the CMs 210 goes down. In addition, the monitoring module 220 may speed up recovery of the CM 210 because the monitoring module 220 does not cause each of the CMs 210 to back up the data of the volatile memory 102.

In addition, in Step S903, when the flags of the CMs 210 are not matched with each other (Step S903: No), the monitoring module 220 suppresses start-up of the CM 210 the flag of which is set to “OFF” (Step S909). After that, the monitoring module 220 transmits a start instruction of the recovery processing to the CM 210 the flag of which is set to “ON” and causes the CM 210 to execute the recovery processing (Step S910).

In addition, the monitoring module 220 transmits a start instruction of the power-off processing, to the CM 210 the flag of which is set to “ON” and causes the CM 210 to execute the power-off processing (Step S911). After that, the monitoring module 220 transmits a start instruction of the power-on processing to the CM 210 the flag of which is set to “ON”, causes the CM 210 to execute the power-on processing (Step S912), and terminates the CM recovery processing.

The operation of CM recovery illustrated in FIG. 7 is implemented by the processing through Steps S901 to S903, and Steps S909 to S912. Therefore, the monitoring module 220 may recover the CM 210 having the newer data of the RAM 213, from among the CMs 210. As a result, as illustrated in FIG. 8, the CM 210 having the older data of the RAM 213 is recovered by the CM 210 having the newer data of the RAM 213, and the pieces of control data of the CMs 210 become identical.

(Procedure of the Recovery Processing)

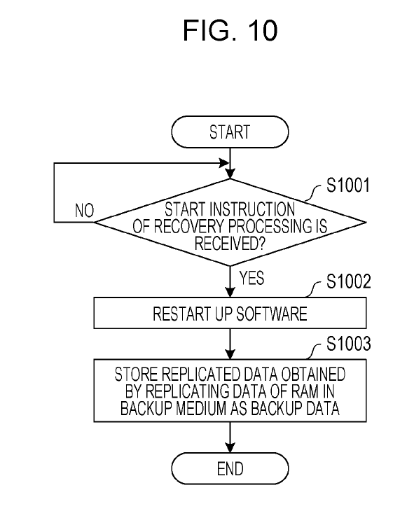

An example of a procedure of the recovery processing by the CM 210 is described below with reference to FIG. 10. The recovery processing is processing that is executed when a start instruction of the recovery processing is received from the monitoring module 220.

FIG. 10 is a method illustrating the example of the procedure of the recovery processing by the CM 210. In FIG. 10, first, the CM 210 determines whether or not a start instruction of the recovery processing is received (Step S1001). Here, when the start instruction of the recovery processing is not received (Step S1001: No), in the CM 210, the flow returns to Step S1001.

In addition, when the start instruction of the recovery processing is received (Step S1001: Yes), the CM 210 restarts up the software without initialization of the RAM 213 (Step S1002). After that, the CM 210 stores replicated data that is obtained by replicating the data of the RAM 213 in the backup medium 214 as backup data (Step S1003). In addition, the CM 210 terminates the recovery processing. Therefore, the CM 210 may back up the data of the RAM 213 without initialization of the data of the RAM 213.

(Power-Off Processing Procedure)

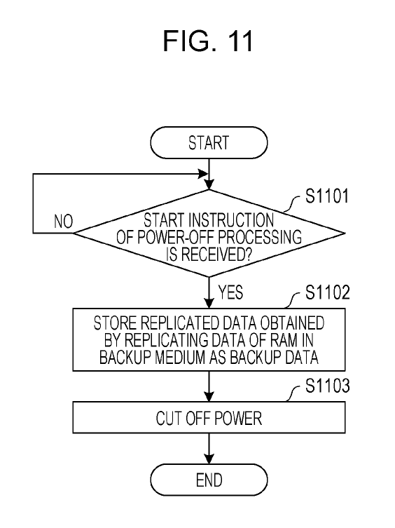

An example of a procedure of the power-off processing by the CM 210 is described below with reference to FIG. 11. The power-off processing is processing that is executed when a start instruction of the power-off processing is received from the monitoring module 220.

FIG. 11 is a method illustrating the example of the procedure of the power-off processing by the CM 210. In FIG. 11, first, the CM 210 determines whether or not a start instruction of the power-off processing is received (Step S1101). Here, when the start instruction of the power-off processing is not received (Step S1101: No), in the CM 210, the flow returns to Step S1101.

In addition, when the start instruction of the power-off processing is received (Step S1101: Yes), the CM 210 stores replicated data that is obtained by replicating the data of the RAM 213 in the backup medium 214 as backup data (Step S1102). In addition, in the CM 210, the power is cut off (Step S1103), and the CM 210 terminates the power-off processing. Therefore, in the CM 210, the power is cut off after the data of the RAM 213 is backed up.

(Power-on Processing Procedure)

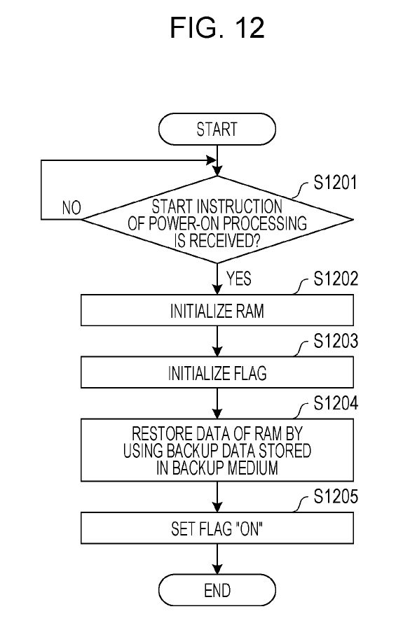

An example of a procedure of the power-on processing by the CM 210 is described below with reference to FIG. 12. The power-on processing is processing that is executed when a start instruction of the power-on processing is received from the monitoring module 220.

FIG. 12 is a method illustrating the example of the procedure of the power-on processing by the CM 210. In FIG. 12, first, the CM 210 determines whether or not a start instruction of the power-on processing is received (Step S1201). Here, when the start instruction of the power-on processing is not received (Step S1201: No), in the CM 210, the flow returns to Step S1201.

In addition, when the start instruction of the power-on processing is received (Step S1201: Yes), the CM 210 initializes the RAM 213 (Step S1202). After that, the CM 210 initializes the flag (Step S1203). In addition, the CM 210 restores the data of the RAM 213 by using the backup data that is stored in the backup medium 214 (Step S1204).

After that, the CM 210 sets the flag to “ON” (Step S1205). In addition, the CM 210 terminates the power-on processing. Therefore, the CM 210 may start the operation.

(Abbreviated Recovery Processing Procedure)

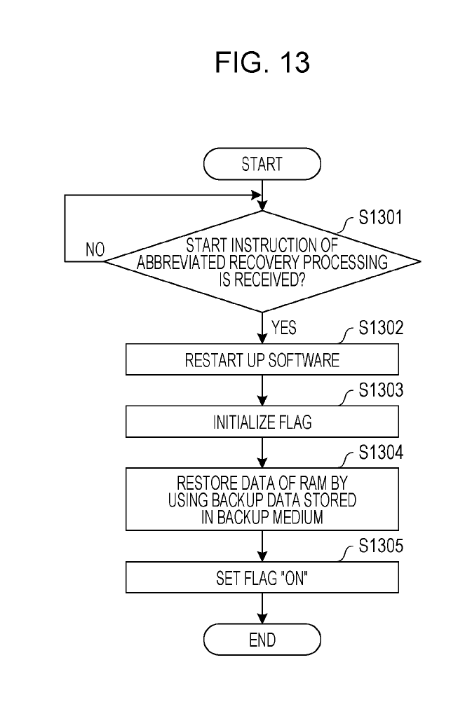

An example of a procedure of the abbreviated recovery processing by the CM 210 is described below with reference to FIG. 13. The abbreviated recovery processing is processing that is executed when a start instruction of the abbreviated recovery processing is received from the monitoring module 220.

FIG. 13 is a method illustrating the example of the procedure of the abbreviated recovery processing by the CM 210. In FIG. 13, first, the CM 210 determines whether or not a start instruction of the abbreviated recovery processing is received (Step S1301). Here, when the start instruction of the abbreviated recovery processing is not received (Step S1301: No), in the CM 210, the flow returns to Step S1301.

In addition, when the start instruction of the abbreviated recovery processing is received (Step S1301: Yes), the CM 210 restarts up the software (Step S1302). After that, the CM 210 initializes the flag (Step S1303).

In addition, the CM 210 restores the data of the RAM 213 by using the backup data that is stored in the backup medium 214 (Step S1304). After that, the CM 210 sets the flag to “ON” (Step S1305). In addition, the CM 210 terminates the abbreviated recovery processing. Therefore, the CM 210 may start the operation.

(Procedure of the Integration Processing)

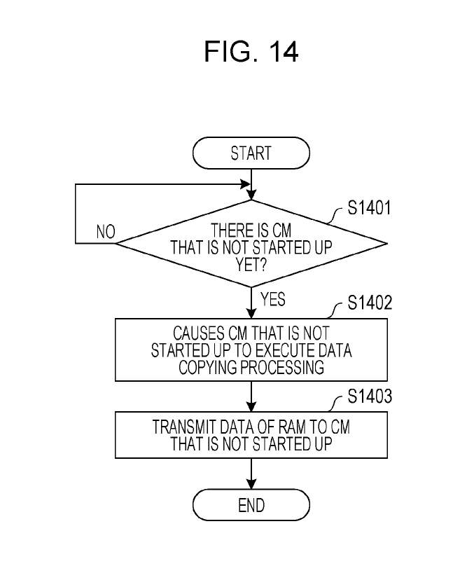

An example of a procedure of the integration processing by the CM 210 is described below with reference to FIG. 14. The integration processing is processing that is executed when the CM 210 that is not started up yet is detected.

FIG. 14 is a method illustrating the example of the procedure of the integration processing by the CM 210. In FIG. 14, first, the CM 210 determines whether or not there is a CM 210 that is not started up yet (Step S1401). Here, when there is no CM 210 that is not started up yet (Step S1401: No), in the CM 210, the flow returns to Step S1401.

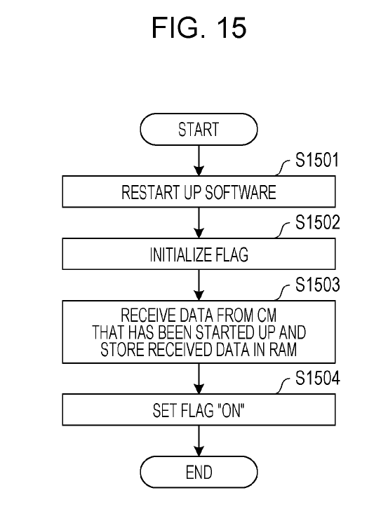

In addition, when there is a CM 210 that is not started up yet (Step S1401: Yes), the CM 210 transmits a start instruction of the data copying processing that is illustrated in FIG. 15, to the CM 210 that is not started up yet and causes the CM 210 to execute the data copying processing (Step S1402). After that, the CM 210 transmits the data of the RAM 213 to the CM 210 that is not started up yet (Step S1403). In addition, the CM 210 terminates the integration processing. Therefore, the CM 210 may recover the other CM 210 by using data of the CM 210.

(Data Copying Processing Procedure)

An example of a procedure of the data copying processing by the CM 210 is described below with reference to FIG. 15. The data copying processing is processing that is executed when a start instruction of the data copying processing is received from the other CM 210.

FIG. 15 is a method illustrating the example of the procedure of the data copying processing by the CM 210. In FIG. 15, first, the CM 210 restarts up the software (Step S1501). After that, the CM 210 initializes the flag (Step S1502). In addition, the CM 210 receives data from the CM 210 that has been started up and stores the received data in the RAM 213 (Step S1503). After that, the CM 210 sets the flag to “ON” (Step S1504). In addition, the CM 210 terminates the data copying processing. Therefore, the CM 210 may be recovered by using the data of the other CM 210.

As described above, the storage device changes the recovery procedure of the control device depending on whether or not backup data of the non-volatile memory of the control device is valid when the control device goes down. For example, when the backup data is valid, the storage device causes the control device to restart up the software and restore the data of the volatile memory by using the backup data of the non-volatile memory. Therefore, the storage device may speed up the recovery of the control device. In addition, the storage device may avoid overwriting of the data of the volatile memory, which is not valid, over the backup data of the non-volatile memory.

In addition, for example, when the backup data is not valid, the storage device causes the control device to restart up the software and back up the data of the volatile memory in the non-volatile memory. In addition, the storage device applies the power to the control device again and causes the control device to restore the data of the volatile memory by using the backup data of the non-volatile memory. Therefore, the storage device may recover the control device into the latest state.

In addition, in a case in which all of the control devices goes down, when the backup data is valid in each of the control devices, the storage device causes all of the control devices to restart the software and restore the data of the volatile memory. Therefore, the storage device may speed up recovery of the control device. In addition, the storage device may avoid overwriting of the data of the volatile memory, which is not valid, over the backup data of the non-volatile memory.

In addition, in a case in which all of the control devices goes down, when the backup data is not valid in each of the control devices, the storage device causes all of the control device to restart the software and back up the data of the volatile memory in the non-volatile memory. In addition, the storage device applies the power to all of the control devices again and causes all of the control devices to restore the data of the volatile memory by using the backup data of the non-volatile memory. Therefore, the storage device may recover the control device into the latest state.

In addition, when all of the control devices goes down, there is a case in which the control device in which the backup data is valid and the control device in which the backup data is not valid are mixed. In this case, the storage device causes the control device in which the backup data is not valid to restart up the software, back up the data of the volatile memory in the non-volatile memory, and restore the data of the volatile memory after application of the power again. In addition, the control device in which the backup data is valid copies the data of the volatile memory of the control device that has been started up. Therefore, the storage device may recover all of the control devices into the identical state.

In addition, the control device stores a flag that indicates whether or not the backup data is valid. Therefore, the storage device may determine whether or not the backup data of the control device is valid, on the basis of the flag, and reduce a work to monitor whether or not the backup data of the control device is valid.

The recovery method that is described above in the embodiment may be implemented when a computer such as a personal computer or a work station executes a program that is prepared beforehand. The recovery program that is described above in the embodiment is recorded in a recording medium that is allowed to be read by a computer such as a hard disk, a flexible disk, a compact disc-read-only memory (CD-ROM), a magneto-optical (MO), or a digital versatile disc (DVD), and is executed so as to be read out from the recording medium by the computer. In addition, the recovery program may be distributed through a network such as the Internet.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A storage device comprising:
a control device that controls an access to storage;
a volatile memory that is included in the control device and stores data including control data that is used for operation control of the control device;
a non-volatile memory that is included in the control device and is a backup destination of the data;
a detection unit that detects a failure occurred in the control device;
a determination unit that determines whether or not backup data that is stored in the non-volatile memory is valid when the detection unit detects the failure occurred in the control device; and
a control unit that causes the control device to execute a first processing of restoring the backup data of the non-volatile memory in the volatile memory after restart-up without backup of the data of the volatile memory, when the determination unit determines that the backup data of the non-volatile memory is valid.

2. The storage device according to claim 1, wherein
when the determination unit determines that the backup data of the non-volatile memory is not valid, the control unit causes the control device to sequentially execute a second processing of backing up the data of the volatile memory in the non-volatile memory after restart without initialization of the volatile memory and a third processing of restoring the backup data of the non-volatile memory in the volatile memory after back-up of the data of the volatile memory in the non-volatile memory and restart.

3. The storage device according to claim 1, wherein
the control device includes a flag that indicates whether or not the backup data of the non-volatile memory is valid, sets the flag valid when the volatile memory is initialized or when the data of the volatile memory is backed up into the non-volatile memory, and sets the flag invalid when the backup data of the non-volatile memory is restored in the volatile memory or when the data of the volatile memory is updated, and
the determination unit refers to the flag and determines that the backup data of the non-volatile memory is valid when the flag is valid.

4. The storage device according to claims 1, wherein
in a case in which there is a plurality of control devices, when the detection unit detects a failure occurred in the plurality of control devices, the determination unit determines whether or not the backup data of the non-volatile memory that is included in each of the plurality of control devices is valid, and
when the determination unit determines that the backup data of the non-volatile memory that is included in each of the control devices is valid, the control unit causes each of the control devices to execute the first processing.

5. The storage device according to claim 4, wherein
when the determination unit determines that the backup data of the non-volatile memory that is included in the each of the control devices is not valid, the control unit causes the each of the control devices to sequentially execute the second processing and the third processing.

6. The storage device according to claim 4, wherein
when in the plurality of control devices, there are a first control device in which the determination unit determines that the backup data of the non-volatile memory is valid and a second control device in which the determination unit determines that the backup data of the non-volatile memory is not valid, the control unit causes the first control device to sequentially execute the second processing and the third processing,
the first control device restarts up the second control device after execution of the third processing and transmits data of a volatile memory that is included in the first control device, to the second control device, and
the second control device stores the data that is received from the first control device in the volatile memory that is included in the second control device after restart-up.

7. A recovery method executed by a computer, comprising:
detecting a failure occurred in a control device that controls an access to storage;
determining whether or not backup data is valid, the backup data being stored in a non-volatile memory that is a backup destination of data stored in a volatile memory and including control data used for operation control of the control device, when it is detected that a failure occurs in the control device; and
causing, when it is determined that the backup data of the non-volatile memory is valid, the control device to execute a first processing of restoring the backup data of the non-volatile memory in the volatile memory after restart-up without backup of the data of the volatile memory.

8. A computer-readable recording medium having stored therein a program for causing a computer to execute a recovery process, the process comprising:
detecting a failure occurred in a control device that controls an access to storage;
determining whether or not backup data is valid, the backup data being stored in a non-volatile memory that is a backup destination of data stored in a volatile memory and including control data used for operation control of the control device, when it is detected that a failure occurs in the control device; and
causing, when it is determined that the backup data of the non-volatile memory is valid, the control device to execute a first processing of restoring the backup data of the non-volatile memory in the volatile memory after restart-up without backup of the data of the volatile memory.
